(19) United States
(12) Patent Application Publication
(10) Pub. No.: US 2014/0154510 A1
(43) Pub. Date: Jun. 5, 2014

(54) FILM STRUCTURE AND METHOD FOR PRODUCING SAME

(71) Applicants: Akihiro Odagawa, Osaka (JP); Akio Matsushita, Kyoto (JP); Nozomu Matsukawa, Nara (JP)

(72) Inventors: Akihiro Odagawa, Osaka (JP); Akio Matsushita, Kyoto (JP); Nozomu Matsukawa, Nara (JP)

(73) Assignee: PANASONIC CORPORATION, Osaka (JP)

(21) Appl. No.: 14/131,197

(22) PCT Filed: Jul. 4, 2012
(86) PCT No.: PCT/JP2012/004342

§ 371 Date: Jan. 6, 2014

(30) Foreign Application Priority Data
Jul. 11, 2011 (JP) 2011-152519

(51) Int. Cl. H01L 29/16; C23C 14/08; C23C 14/06; C23C 14/35

(52) U.S. Cl. CPC H01L 29/1606; C23C 14/352; C23C 14/081; C23C 14/0694
USPC 428/408; 204/192.22

(57) ABSTRACT

A film structure (carbon material-insulating film structure) of the present invention includes a carbon material and an insulating film disposed on the carbon material and composed of fluorine-added magnesium oxide. The amount of added fluorine in the magnesium oxide is 0.0049 atomic percent or more and 0.1508 atomic percent or less. This film structure facilitates the realization of an electronic device, such as a spin device, which uses a carbon material such as graphene. This film structure is formed, for example, by sputtering using a target containing magnesium oxide and magnesium fluoride.

### TECHNICAL FIELD

The present invention relates to a film structure including a carbon material and an insulating film disposed on the carbon material, and to a method for producing the film structure.

### BACKGROUND ART

Substances made of carbon (C) take various forms, including diamonds, sheets, nanotubes, horns, and balls such as C₆₀ fullerene. Furthermore, substances made of carbon have various physical properties. Therefore, energetic research and development for application of substances made of carbon have been advanced.

One of the substances made of carbon is graphene. Graphene is in the form of a film composed of a single carbon sheet or several carbon sheets. Graphene is a substance the isolation of which was realized in 2004, and its singular physical properties as a two-dimensional semimetal have been discovered one after another. Graphene has a singular band structure in which two n bands having linear band dispersion intersect at the Fermi energy. Based on this singular band structure, it is expected that, for example, graphene should exhibit a carrier mobility which is ten or more times that of silicon (Si). Therefore, there is a possibility that a high-speed and low-consumption electronic device can be realized by use of graphene.

Furthermore, since graphene is composed of carbon which is a light element, the spin-orbit interaction in graphene is weak, and the crystallinity of graphene is high. Therefore, in graphene, the spin relaxation length required for transmission of electron spin information is long, and specifically is several microns. Graphene has drawn attention also as a material for spin electronics (See Non Patent Literature 1, 2, and 3).

These physical properties characteristic of graphene are largely derived from its crystal structure composed of a network of six-membered rings. In view of this, materials suitable for a layer disposed on graphene have been sought in order to apply graphene to electronic devices such as field-effect transistors (FETs) and spin devices.

Non Patent Literature 1 discloses an arrangement in which cobalt (Co), which is a metal having a close-packed hexagonal lattice and being well lattice-matched to graphene, is disposed on graphene, and also discloses spin injection into graphene in this arrangement.

An arrangement in which an insulating film is disposed on graphene has also been tested. Non Patent Literature 4 discusses an arrangement in which boron nitride (h-BN) having a six-membered ring structure as in graphene and having a crystal lattice well-matched to graphene is disposed on graphene. Non Patent Literature 2 discloses an example where magnesium oxide (MgO) serving as an insulating film is interposed between graphene and a Co layer.

Non Patent Literature 5 discloses that, for the realization of spin devices that play a central role in spin electronics, a material having a high degree of spin polarization is preferable, and a long spin relaxation length in the carbon material is favorable.

### CITATION LIST

### Non Patent Literature

Non Patent Literature 1: Advanced Functional Materials, vol. 19, pp. 3711-3716 (2009)

Non Patent Literature 2: Physical Review B, vol. 77, 020402R (2008)

Non Patent Literature 3: Applied Physics Letters, vol. 93, 183107 (2008)

Non Patent Literature 4: Solid State Communications, vol. 116, pp. 37-40 (2000)

Non Patent Literature 5: OYO BUTURI (Applied Physics), vol. 77, pp. 255-263 (2008)

### SUMMARY OF INVENTION

### Technical Problem

With these conventional techniques, effective spin injection into graphene from a layer such as a Co layer disposed on the graphene is not necessarily achieved, and for this and other reasons, it is practically difficult to realize an electronic device using graphene. In actually designing an electronic device, other techniques than the above, such as use of a carbon material having a similar crystal structure to graphene, and use of a carbon material having a surface with a graphene layer formed thereon, are taken into consideration. In view of these facts, a structure composed of films (a film structure) that facilitates the realization of an electronic device using a carbon material such as graphene has been desired.

### Solution to Problem

A film structure of the present invention is a film structure (carbon material-insulating film structure) including a carbon material and an insulating film disposed on the carbon material and composed of fluorine-added magnesium oxide. The amount of added fluorine in the magnesium oxide is 0.0049 atomic percent or more and 0.1508 atomic percent or less.

A production method of the present invention is a method for producing a film structure including a carbon material and an insulating film disposed on the carbon material. The method includes forming an insulating film composed of fluorine-added magnesium oxide on the carbon material by sputtering using a target containing magnesium oxide and magnesium fluoride. The amount of added fluorine in the insulating film is 0.0049 atomic percent or more and 0.1508 atomic percent or less.

### Advantageous Effects of Invention

The film structure of the present invention is a film structure that facilitates the realization of an electronic device using a carbon material such as graphene, and includes a carbon material and an insulating film disposed on the carbon material. With the production method of the present invention, the insulating film having added thereto a specific amount of fluorine can be formed in such a manner as to have high compositional uniformity, and the above film structure can be obtained which exhibits a favorable feature of, for example, allowing efficient spin injection into the carbon material.

### BRIEF DESCRIPTION OF DRAWINGS

FIG. 1 is a schematic structural cross-sectional view showing an example of a film structure of the present invention.

FIG. 2 is a schematic diagram for illustrating an example of a method for producing a film structure of the present invention.

FIG. 3 is a schematic diagram for illustrating another example of a method for producing a film structure of the present invention.

FIG. 4 is a diagram showing an example of a flowchart for the production of a film structure of the present invention.

FIG. 5 is a diagram showing relationships evaluated in Examples between the conditions for forming insulating films and the amounts of added fluorine in the insulating films.

FIG. 6 is a diagram showing results of comparison between the actual measured values and calculated values of the amounts of fluorine contained in the insulating films formed in Examples.

FIG. 7 is a diagram showing wide-angle X-ray diffraction profiles for film structures fabricated in Examples.

FIG. 8 is a schematic diagram for illustrating a method used in Examples for evaluating the spin injection properties of a stack of a film structure and a magnetic material film.

### DESCRIPTION OF EMBODIMENTS

With conventional techniques, it is practically difficult to realize an electronic device using a carbon material such as graphene. A specific description will be given below.

Non Patent Literature 1 discloses spin injection into graphene in an arrangement in which a Co layer is disposed on the graphene. However, the conductivity modulation achieved by this spin injection is extremely small, and specifically is no more than 0.02%. Such extremely small conductivity modulation insufficient for the realization of a spin device is thought to be due to the low degree of spin polarization of Co (0.42 in terms of spin polarizability) and to the impedance mismatch between the graphene and the Co layer.

Even when it is attempted to realize a spin device by a combination of graphene with a highly spin-polarizable magnetic material on the basis of descriptions of Non Patent Literature 5, a problem with crystal lattice match arises. Known examples of the highly spin-polarizable magnetic material include FeCo alloys, Fe₃O₄, and Heusler alloys. These magnetic materials are used, for example, in magnetoresistive devices. However, these materials are poorly lattice-matched to the crystal structure of graphene, since the crystal structure of FeCo alloys is a body-centered cubic lattice structure, and the crystal structure of Fe₃O₄ and Heusler alloys is a spinel structure. Therefore, it is difficult to realize a spin device simply by disposing a magnetic material on graphene.

The present inventors have focused attention on disposing an insulating film on graphene. However, with conventional techniques for disposing an insulating film on graphene, it is still not possible to realize an electronic device.

Non Patent Literature 4 discloses disposing a h-BN insulating film on graphene. The h-BN is well lattice-matched to graphene. However, according to Non Patent Literature 4, a high temperature of up to about 800° C. is required for formation of the h-BN insulating film. The insulating film formation process at such a high temperature is poorly compatible with semiconductor processes used for production of electronic devices, particularly the latest fine-scale semiconductor processes. Therefore, h-BN insulating films cannot be employed for production of electronic devices.

Non Patent Literature 2 discloses an example where magnesium oxide (MgO) serving as an insulating film is interposed between graphene and a Co layer in order to improve the impedance match between the graphene and the Co layer. In this example, however, conductivity modulation is not achieved by spin injection at a room temperature, and the performance is reduced compared to when a Co layer is disposed directly on graphene. According to a study by the present inventors, this reduction in performance indicates the low crystallinity of the interposed MgO film and the occurrence of spin scattering largely due to the low crystallinity.

The temperature for crystal growth of MgO is low, and specifically is 400° C. or less. Therefore, a process for forming an insulating film composed of MgO is highly compatible with semiconductor processes. In addition, MgO and the highly spin-polarizable magnetic materials mentioned above are well lattice-matched. Therefore, if an insulating film composed of MgO can be disposed on graphene with the film being highly crystal-orientated, the film can be used, for example, as a tunnel insulating film for connecting graphene to a magnetic material. In consideration of the high dielectric constant of MgO which is 9.8 (this value is more than twice the dielectric constant of silicon oxide which is 4.2), the film can be used also as a gate insulating film.

Hitherto, there has not been known a method by which an insulating film composed of MgO and having a high degree of crystal orientation can be disposed on graphene. For example, Non Patent Literature 3 describes growth of MgO on graphene; however, oriented growth of MgO crystal is not achieved in this literature. This is thought to be due to poor lattice match between MgO and a carbon material such as graphene. The crystal structure of graphene is composed of a network of six-membered rings, and has a lattice constant of 0.25 nm or 0.14 nm. On the other hand, MgO has a crystal structure that has a lattice constant of 0.42 nm and that is a cubic crystal structure of the sodium chloride type. Therefore, it is difficult to allow oriented growth of MgO crystal simply by disposing MgO on a carbon material.

In a film structure of the present invention (carbon material-insulating film structure; structure of a carbon material and an insulating film disposed on the carbon material), an insulating film composed of MgO and having a high degree of crystal orientation is provided on a carbon material, despite poor lattice match between the carbon material and MgO. This is achieved by addition of a specific amount of fluorine into MgO. With such a film structure, various electronic devices using a carbon material can be realized, such as a spin device including the insulating film as a tunnel insulating film, and a field-effect transistor including the insulating film as a gate insulating film. In view of good lattice match between MgO and a magnetic material having a high degree of spin polarization, this film structure strongly promotes the realization of a spin device capable of efficient spin injection into a carbon material. As a matter of course, this film structure can be applied not only to spin devices but also to various electronic devices, since the formation temperature is 400° C. or less and the formation process has excellent compatibility with semiconductor processes. An electronic device including the film structure is expected to function as a high-speed and low-consumption device by virtue of the carbon material, as exemplified by graphene.

Embodiments of the present invention will be described below with reference to the drawings.

Graphene is in the form of a film composed of a single carbon sheet or several carbon sheets. Hereinafter, graphene composed of two or more layers is referred to as “multi-layer graphene”, and single-layer graphene is simply referred to as “graphene”.

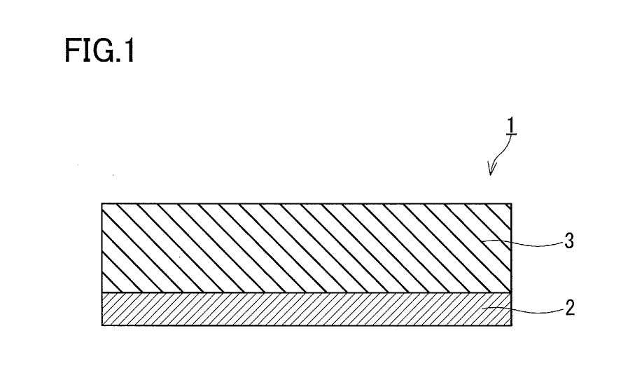

In the embodiment shown in FIG. 1, a film structure 1 is a carbon material-insulating film structure including a carbon material 2 and an insulating film 3 disposed on the carbon material 2. In the film structure 1, the carbon material 2 and the insulating film 3 are in contact with each other. The insulating film 3 is composed of fluorine-added MgO. The amount of added fluorine in the insulating film 3 (the amount of added fluorine in MgO composing the insulating film 3) is 0.0049 atomic percent (atm %) or more and 0.1508 atm % or less.

The carbon material 2 is, for example, graphene, multi-layer graphene, a carbon material having a similar crystal structure to graphene, or a carbon material having a surface with graphene or multi-layer graphene formed thereon. The carbon material 2 preferably contains graphene and/or multi-layer graphene, and is more preferably graphene or multi-layer graphene. The surface of the carbon material 2 that is in contact with the insulating film 3 is preferably composed of graphene, multi-layer graphene, or a layer having a similar crystal structure to graphene, and is more preferably composed of graphene or multi-layer graphene.

When an electronic device is built using the film structure 1, the carbon material 2 can function, for example, as an electrically-conductive film, a spin injection film, or a channel material of a field-effect transistor.

The MgO of the insulating film 3 has a high degree of crystal orientation. The orientation of MgO is usually (100) orientation. When an electronic device is built using the film structure 1, the insulating film 3 can function, for example, as a tunnel insulating film, a protecting insulating film, an interlayer insulating film, or a gate insulating film of a field-effect transistor.

The use of the film structure 1 is not particularly limited. The film structure 1 can be used in combination with another layer, another film, and/or another member, as necessary. Examples of the other layer, film, and member that can be combined with the film structure 1 used in an electronic device include a substrate, a semiconductor layer (film), a metal layer (film), a magnetic material layer (film), and an insulating layer (film). In the case of use in a spin device, for example, a magnetic material layer (film) is stacked on the film structure 1 so as to be in contact with the insulating film 3. In this case, spins can be injected into the carbon material 2 from the magnetic material layer (film) using the insulating film 3 as a tunnel insulating film, and the film structure 1 functions as a part of the spin device. An example of the spin device is a magnetoresistive device. The substrate is, for example, a silicon substrate, a quartz substrate, or a glass substrate. The silicon substrate may have a surface with a thermally-oxidized film formed thereon by thermal oxidation. The quartz substrate may be a fused quartz substrate. The magnetic material composing the magnetic material layer (film) is, for example, a FeCo alloy, Fe₃O₄, or a Heusler alloy. These ferromagnetic materials are highly spin-polarizable (Fe₃O₄ and Heusler alloys have been predicted as half-metallic magnetic substances by band calculation). Therefore, when a magnetic material layer (film) composed of any of these magnetic materials is used as a spin injection electrode, the properties as the spin device are improved.

The method for producing the film structure 1 is not particularly limited. In one embodiment of the method for producing the film structure 1, the insulating film 3 is formed on the carbon material 2 by sputtering using a target containing magnesium oxide and magnesium fluoride.

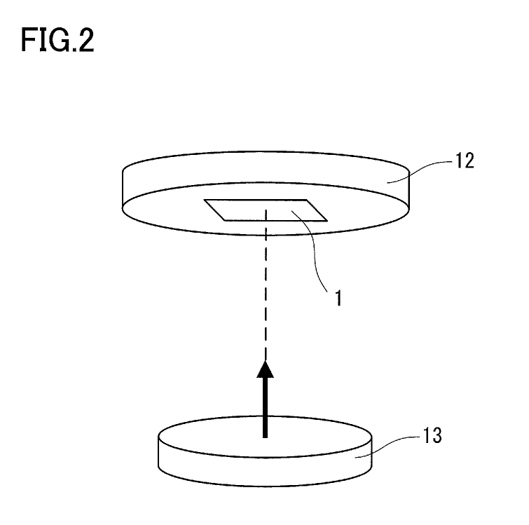

FIG. 2 shows an example of forming the insulating film 3 on the carbon material 2 by the sputtering. In the example shown in FIG. 2, the film structure 1 is formed by sputtering using a target 13 composed of a mixture of magnesium oxide (MgO) and magnesium fluoride (MgF₂). The numeral 12 denotes a heating holder 12. More specifically, in the example shown in FIG. 2, an insulating film composed of fluorine-added MgO is formed on a carbon material disposed on the heating holder 12 by sputtering using the target 13, and the amount of added fluorine in the insulating film is 0.0049 atm % or more and 0.1508 atm % or less. In FIG. 2, the thus-formed insulating film is shown as the film structure 1.

The specific composition of the target is not particularly limited as long as the target contains MgO and MgF₂. The target may be composed of a mixture of MgO and MgF₂ as in the example shown in FIG. 2. The mixture is, for example, a sintered body of a mixed crystal of MgO and MgF₂. The target may contain MgO and MgF₂ that are in a state of being separated from each other. Such a target has, for example, a structure in which a single crystal or sintered body composed of MgF₂ is disposed on a single crystal or sintered body composed of MgO.

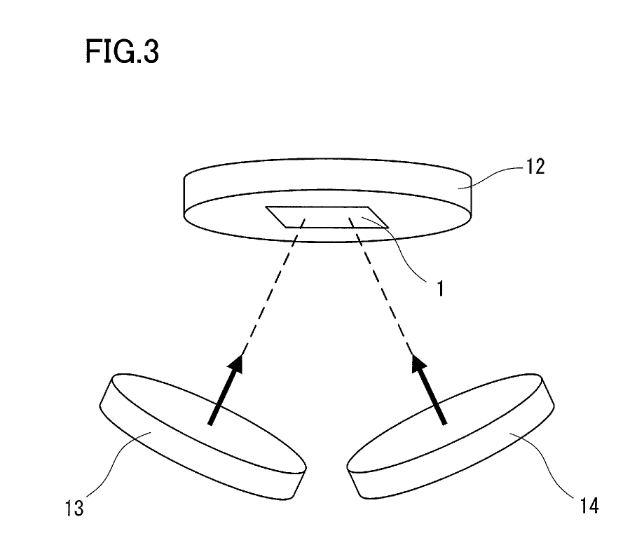

For forming the insulating film 3 on the carbon material 2 by sputtering, sputtering using a combination of the target containing MgO and MgF₂ with another additional target can be employed. FIG. 3 shows an example of forming the insulating film 3 on the carbon material 2 by such sputtering.

In the example shown in FIG. 3, the insulating film 3 is formed on the carbon material 2 disposed on the heating holder 12 by co-sputtering using the target 13 composed of a mixture of MgO and MgF₂ and an additional target 14 composed of MgO, and thus the film structure 1 is obtained. More specifically, in the example shown in FIG. 3, an insulating film composed of fluorine-added MgO is formed on a carbon material by co-sputtering using the target 13 and the additional target 14 composed of MgO, and the amount of added fluorine in the insulating film is 0.0049 atm % or more and 0.1508 atm % or less. In FIG. 3, the thus-formed insulating film is shown as the film structure 1.

With the method shown in FIG. 3, the amount of added fluorine in the insulating film 3 is controlled more easily, and the uniformity of fluorine addition in the insulating film 3 is improved despite the very slight amount of added fluorine.

The target 14 is composed of MgO. The target 14 is, for example, a single crystal or sintered body composed of MgO.

In the methods shown in FIGS. 2 and 3, the insulating film 3 is preferably formed on the carbon material 2 at a temperature in the range of a room temperature to 400° C. It is more preferable to first heat the carbon material 2 to a temperature of 350° C. or more and 400° C. or less, subsequently cool the carbon material 2 to a temperature in the range of a room temperature to 200° C., and then form the insulating film 3 on the carbon material 2.

For the formation of the insulating film 3 on the carbon material 2 as shown in FIGS. 2 and 3, a conventional sputtering method can be employed, as long as sputtering or co-sputtering is carried out using the above-mentioned specific target, and the preferable temperature range for the formation of the insulating film 3 is the temperature range mentioned above.

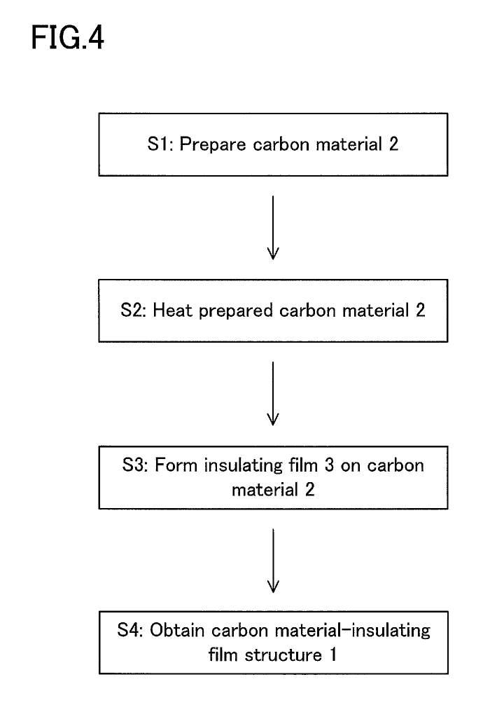

FIG. 4 shows an example of a flowchart for the production of the film structure 1.

In the example shown in FIG. 4, the carbon material 2 is prepared first (S1). The carbon material 2 can be prepared by a commonly-known method. Graphene or multi-layer graphene contained in the carbon material 2 can be obtained, for example, by chemical vapor deposition (CVD), by exfoliation of highly oriented pyrolytic graphite (HOPG) that is a graphite crystal, by high-temperature heating of silicon carbide (SiC) single crystal, or by formation of a carbon film on sapphire single crystal, Ni, iron (Fe), Co, ruthenium (Ru), or copper (Cu).

Next, the prepared carbon material 2 is heated (heating step S2). This improves the cleanliness of the surface of the carbon material 2. The temperature for heating the carbon material 2 is preferably 200° C. or more and 400° C. or less. Preferably, the carbon material 2 is heated first to a temperature of 350° C. or more and 400° C. or less (typically 350° C.), and is then cooled to and maintained at a temperature in the range of a room temperature to 200° C. (typically a room temperature or 200° C.). The step S2 may be performed as necessary.

Next, the insulating film 3 is formed on the carbon material 2 (deposition step S3). The formation of the insulating film 3 is performed, for example, by the sputtering shown in FIG. 2 or FIG. 3. In this manner, the carbon material-insulating film structure 1 is obtained (S4).

Another step can be carried out in addition to S1 to S4, as long as the film structure 1 can be obtained.

### EXAMPLES

Hereinafter, the present invention will be described in more detail using examples. The present invention is not limited to the examples presented below.

### Example 1

[Formation of Insulating Film on Carbon Material]

First, a carbon material 2 that was multi-layer graphene was prepared by reference to Science, vol. 306, p. 666-p. 669 (2004). Specifically, a cellophane adhesive tape was pressed against a 1 mm-thick highly oriented pyrolytic graphite (HOPG) to exfoliate a crystalline flake. A cellophane adhesive tape was further pressed against the exfoliated crystalline flake to exfoliate a part of the crystalline flake and thus to obtain a thinner flake. The operation of exfoliating a part of an obtained flake with a cellophane adhesive tape was repeated a plurality of times, and then the resultant HOPG flake on a cellophane tape was rubbed onto a silicon (Si) single-crystal substrate on the surface of which an oxide film (SiO₂ film) having a thickness of about 300 nm was formed. When the thickness of the carbon material 2 on the Si substrate was evaluated using an atomic force microscope (AFM), the thickness was about 1±0.5 nm. That is, the carbon material 2 was multi-layer graphene. It was separately confirmed that the same result can be obtained also in the case of using a substrate composed of a material other than Si, as long as the substrate has a strength sufficient for disposing a flake. In addition, it was separately confirmed that HOPG having a thickness of about several micrometers does not require use of a substrate.

Next, the carbon material 2 was fixed to a heating holder together with the Si substrate, and was placed in a vacuum apparatus for carrying out inductively-coupled magnetron sputtering. Next, the pressure (the degree of vacuum) in the vacuum apparatus was adjusted to 5×10⁻⁷ Torr or less, and then the carbon material 2 was heated by the heating holder. In the heating, the temperature of the carbon material 2 was increased from a room temperature to 350° C. over 30 minutes. After the temperature reached 350° C., the carbon material 2 was cooled to 200° C., and thereafter maintained at 200° C. during formation of the insulating film 3.

The formation of the insulating film 3 on the carbon material 2 was performed by co-sputtering shown in FIG. 3 using the two types of targets 13 and 14. A MgO single-crystal target (manufactured by Tateho Chemical Industries Co., Ltd. and having a size (diameter) φ of 2 inches) having a purity of 3N (99.9%) was used as the first target 14 composed of MgO. A target used as the second target containing MgO and MgF₂ was a target including: a MgO sintered target (manufactured by Kojundo Chemical Laboratory Co., Ltd. and having a size (diameter) φ of 2 inches) having a purity of 4N (99.99%); and three MgF₂ chips (manufactured by Kojundo Chemical Laboratory Co., Ltd. and having a size of 5 mm×5 mm×2 mm thickness) having a purity of 4N (99.99%) and attached on the MgO sintered target.

The formation of the insulating film 3 on the carbon material 2 was carried out in an argon atmosphere with a pressure of 4.05 Pa under the conditions that the RF coil output was 50 W, and the RF cathode power was between 0 and 150 W. The amount of added fluorine in the insulating film 3 was controlled by varying the input power for the first target 14 in the range of 0 W to 150 W, and by varying the input power for the second target 13 in the range of 0 W to 50 W (see Table 2).

In advance of the formation of the insulating film 3, the relationship (sputter rate) of the film thickness to the input powers for the targets and to the sputtering time was evaluated by carrying out a film formation test using each of the first and second targets 14 and 13 alone, in order to control the thickness of the insulating film 3 to be formed. When the insulating film 3 was actually formed, the sputtering time (film formation time) was determined in consideration of the sputter rate determined for each target so that an insulating film 3 having a desired thickness was obtained. In the present example, an insulating film 3 having a thickness of 50 nm was formed.

In the present example, the insulating film 3 was formed on the carbon material 2 in the above manner, and the film structure 1 was thus obtained.

[Method for Evaluating Amount of Added Fluorine in Formed Insulating Film]

Aside from the fabrication of the film structure, examination as described below was performed in order to determine the method for evaluating the amount of added fluorine in an insulating film formed on a carbon material.

Using the same method as for the above formation of the insulating film 3, an insulating film for evaluation (having a thickness of 50 nm) was separately formed on a Si substrate having a thermally-oxidized film formed thereon. The relationship between the conditions for forming an insulating film and the amount of fluorine contained in the formed insulating film was evaluated.

The amount of fluorine contained in the insulating film formed for evaluation was evaluated by a combination of secondary ion mass spectroscopy (SIMS) with ion milling. The ion milling was used to evaluate variation in the amount of fluorine across the thickness direction of the insulating film. The value of the amount of fluorine measured by SIMS was quantified using a value measured for a standard sample. The standard sample was prepared as follows: magnetron sputtering using a target composed of MgO was performed to form a MgO film on a Si substrate having a thermally-oxidized film formed thereon, and then fluorine was implanted at 10²⁰/cc into the formed MgO film by ion implantation.

The measured amount of fluorine obtained by SIMS measurement was calculated in terms of “number of atoms/cc” using a value measured for the standard sample, and then the ratio of the calculated value to the number of atoms/cc calculated from the specific gravity and formula weight of MgO was determined. Thus, the amount (atm %) of fluorine in the insulating film for evaluation was calculated. Specifically, since the specific gravity and formula weight of MgO are respectively 3.6 and 40.304, the number of Mg atoms and the number of O atoms per 1 cc of MgO are each calculated as about 0.538×10²³ from the formula 3.6/40.304×Avogadro number. The ratio of the number of fluorine atoms to 1.076×10²³ which is the sum of the numbers of Mg atoms and O atoms was determined as the atomic percent (atm %) of added fluorine in MgO.

Five types of insulating films for evaluation were prepared. Specifically, three of the samples (fluorine-added sample 1, fluorine-added sample 2, and fluorine-added sample 3) each included a fluorine-added MgO film formed by supplying power both to the first target 14 composed of MgO and to the second target 13 containing MgO and MgF₂, while the other two samples (reference sample 1 and reference sample 2) each included a non-fluorine-added MgO film formed without supplying power to the second target.

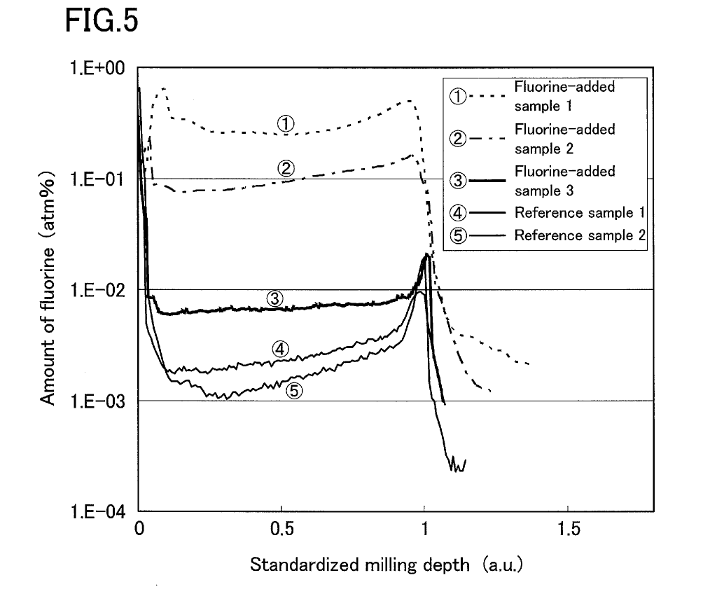

FIG. 5 shows the results of evaluation of the amounts of fluorine in the samples. In FIG. 5, the vertical axis represents the amounts (atm %) of fluorine contained in the samples, and the horizontal axis represents standardized milling depths (a. u.). FIG. 5 shows the variation in the amount of fluorine across the thickness direction of each insulating film. Here, the “standardized milling depth” means a relative milling depth with respect to the thickness of the evaluated insulating film from the surface to the bottom (the interface between the film and the substrate), the relative milling depth being determined on the assumption that the insulating film was drilled at a constant rate over the milling time. The surface of the insulating film is at a standardized milling depth of “0”, and the bottom is at a standardized milling depth of “1”. For the bottom of the insulating film, it was determined that ion milling was completed up to the bottom of the insulating film (up to the substrate) at a moment in milling time when the ¹⁸O signal being concurrently measured was sharply decreased.

In the present example, for each sample, the quantified values of the amount of fluorine in the region within ±10% of the thickness from the center of the insulating film in the thickness direction (the center was at a standardized milling depth of 0.5) were averaged, and the resultant average value was defined as an actual measured value of the amount of fluorine in the sample. Thus, the regions of the insulating film each of which was within 40% of the thickness from the interface between the film and an adjacent layer were excluded from evaluation, and the influence of the interfaces on the obtained amount of fluorine was eliminated.

Table 1 shows the amounts of fluorine in the samples. Table 1 also shows background (BG) corrected values each obtained by subtraction of a background value determined as the average value of the reference samples 1 and 2.

TABLE 1

| | | | Amount of fluorine (atm %) | |
|---|---|---|---|---|
| | Input power (W) | | Actual, | |
| | First target | Second target | measured | BG corrected |
| | (MgO) | (MgF₂/MgO) | value | value |
| Fluorine-added | 0 | 50 | 0.25370 | 0.25182 |
| sample 1 | | | | |
| Fluorine-added | 150 | 50 | 0.09247 | 0.09058 |
| sample 2 | | | | |
| Fluorine-added | 150 | 5 | 0.00675 | 0.00487 |
| sample 3 | | | | |
| Reference | 150 | 0 | 0.00147 | — |
| sample 1 | | | | |
| Reference | 150 | 0 | 0.00229 | — |
| sample 2 | | | | |

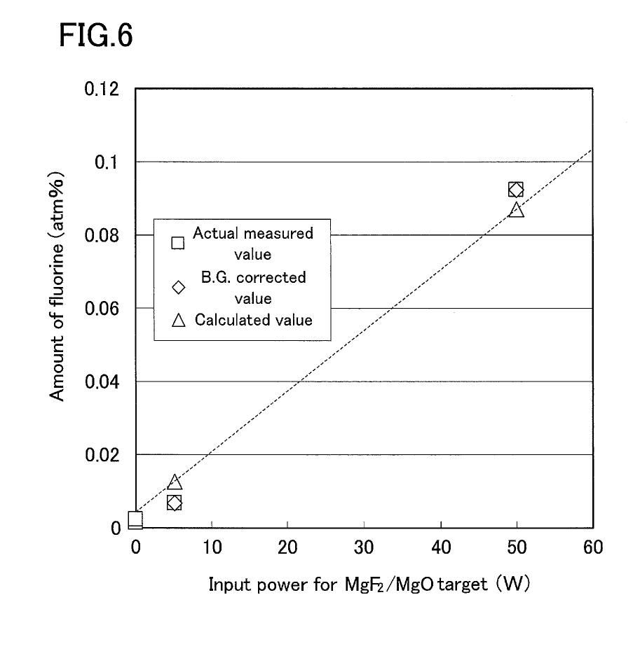

The insulating films formed by co-sputtering can be considered to be layers for which the concentration of fluorine in fluorine-containing MgO derived from the second target was diluted by MgO derived from the first target. The degree of dilution can be determined from the power input to each target (the film formation rate derived from each target). In view of this, the amounts of fluorine in the fluorine-added samples 2 and 3 and the reference samples 1 and 2 were calculated from the ratios between the film formation rates, based on the BG corrected value for the fluorine-added sample 1 formed by supplying power only to the second target. FIG. 6 shows the results of comparison between the thus-calculated amounts of fluorine and the actual measured values obtained by SIMS. In FIG. 6, the horizontal axis represents the powers input to the second target (MgF₂/MgO target), and the vertical axis represents the amounts of fluorine contained in the samples. FIG. 6 shows that the BG corrected values determined by SIMS measurements almost coincided with the values calculated from the film formation rates. That is, it was found that the values of the amount of fluorine that are almost equal to actual measured values obtained by SIMS can be calculated from film formation rates.

Therefore, in the present example, for an insulating film formed under film formation conditions for which an actual measured value obtained by SIMS was given, a BG corrected value based on the actual measured value was defined as the value of the amount of fluorine. For an insulating film formed under film formation conditions for which no actual measured value obtained by SIMS was given, a value calculated from the film formation rate (sputtering rate) was defined as the value of the amount of fluorine. Table 2 given below shows the amounts of fluorine (the amounts of added fluorine) in insulating films formed under different conditions.

TABLE 2

| Conditions for | | | | |
|---|---|---|---|---|
| forming | Input power (W) | | Amount of fluorine (atm %) | |
| insulating | First target | Second target | Calculated | BG corrected |
| film | (MgO) | (MgF₂/MgO) | value | value |
| Reference | 150 | 0 | 0.00000 | — |
| conditions | | | | |
| Conditions A | 150 | 5 | — | 0.00487 |
| Conditions B | 150 | 15 | 0.03441 | — |
| Conditions C | 150 | 25 | 0.05256 | — |
| Conditions D | 150 | 50 | — | 0.09058 |
| Conditions E | 53 | 50 | 0.15080 | — |
| Conditions F | 30 | 50 | 0.18259 | — |
| Conditions G | 0 | 50 | — | 0.25182 |

[Evaluation of Crystal Orientation in Formed Insulating Film]

A film structure (Example 1-1) obtained by forming an insulating film 3 on a carbon material 2 under the film formation conditions B shown in Table 2, and a film structure (Comparative Example 1-1) obtained by forming an insulating film on a carbon material 2 under the reference conditions were subjected to wide-angle X-ray diffraction measurements to evaluate the state of the crystal orientation of each insulating film. Formation of the insulating film composed of non-fluorine-added MgO in Comparative Example 1-1 was performed in the same manner as in the above-described formation of the insulating film 3, except that no power was supplied to the second target.

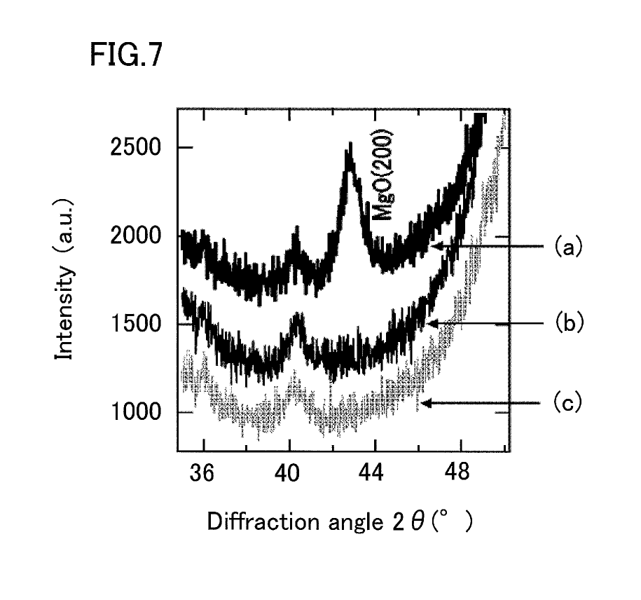

FIG. 7 shows X-ray diffraction profiles for the film structure of Example 1-1, the film structure of Comparative Example 1-1, and a carbon material 2 on which no insulating film was formed. In FIG. 7, (a) represents the diffraction profile of Example 1-1, (b) represents the diffraction profile of Comparative Example 1-1, and (c) represents the diffraction profile of the carbon material. As shown in FIG. 7, in Example 1-1 including a MgO insulating film which was formed under the conditions B and in which the amount of added fluorine was 0.0344 atm %, a strong diffraction peak of the (200) plane characteristic of the oriented crystal of MgO was observed at a diffraction angle 2θ of 42.9°. In a MgO crystal, a diffraction peak of the (100) plane does not appear according to the extinction rule. Therefore, the crystallinity and orientation of the MgO crystal can be evaluated by the peak derived from the high-order (200) reflection. On the other hand, in Comparative Example 1-1 including a MgO insulating film which was formed under the reference conditions and in which the amount of added fluorine was 0.0000 atm %, a diffraction peak derived from the (200) plane of the MgO crystal was not observed, and even diffraction peaks derived from other crystal planes were not observed either. That is, it was confirmed that the degree of crystal orientation of the insulating film included in Comparative Example 1-1 was low. Therefore, the results shown in FIG. 7 confirmed that a MgO insulating film oriented in the (100) direction can be formed on a carbon material by addition of a specific amount of fluorine.

Similarly, the states of the crystal orientations of the insulating films 3 formed on the carbon materials 2 under the other conditions were evaluated by wide-angle X-ray diffraction measurements. The evaluation results are collectively shown in Table 3 given below, together with the evaluation results for Example 1-1 and Comparative Example 1-1. In Table 3, the values of the intensity (counts per second: cps) of the diffraction peak derived from the (200) plane of the MgO crystal are those resulting from eliminating the diffraction profile (c) shown in FIG. 7 (the diffraction profile of the carbon material on which no insulating film was formed) as a background.

TABLE 3

| | | Input power | Amount of | MgO (200) |
|---|---|---|---|---|
| | | (W) First | added | diffraction |
| | Conditions for | target/ | fluorine in | peak |
| | forming | Second | insulating | intensity |
| | insulating film | target | film (atm %) | (cps) |
| Example | Conditions B | 150/15 | 0.0344 | 1490 |
| 1-1 | | | | |
| Example | Conditions A | 150/5 | 0.0049 | 420 |
| 1-2 | | | | |
| Example | Conditions D | 150/50 | 0.0906 | 1360 |
| 1-3 | | | | |
| Example | Conditions E | 53/50 | 0.1508 | 1250 |
| 1-4 | | | | |
| Comparative | Reference | 150/0 | 0.0000 | No |
| Example | conditions | | | diffraction |
| 1-1 | | | | peak |
| Comparative | Conditions G | 0/50 | 0.2518 | No |
| Example | | | | diffraction |
| 1-2 | | | | peak |

As shown in Table 3, at least when the amount of added fluorine was 0.0049 atm % or more and 0.1508 atm % or less, the diffraction peak derived from the (200) plane of the MgO crystal was observed in the formed insulating film, and formation of a crystal-oriented MgO insulating film on a carbon material was confirmed.

Next, the electrical resistance value between the carbon material 2 and the insulating film 3 was evaluated for each of the fabricated film structures by resistance measurement capable of measurement up to 10 MΩ For all of the samples of Examples, an electrical resistance value of 10 MΩ or more was measured. It was confirmed that all of the insulating films 3 formed in the samples of Examples were insulating bodies having an electrical resistance value of 10 MΩ or more.

In addition, formation of a carbon material-insulating film structure and evaluation of the state of the crystal orientation of the formed insulating film were performed in the same manner as above, except that the conditions for heating the carbon material 2 and the temperature conditions for forming the insulating film were changed. Consequently, results similar to those shown in FIG. 3 were obtained. In the heating of the carbon material in this case, the temperature of the carbon material was increased from a room temperature to 400° C. over 30 minutes. The subsequent formation of the insulating film was performed after the heated carbon material was cooled from 400° C. to a room temperature.

### Example 2

First, a carbon material-insulating film structure 1 was fabricated in the same manner as in the fabrication of Example 1-1, except that the thickness of the insulating film 3 was adjusted to 1.5 nm. Since the fabrication conditions were the same as those for Example 1-1, the amount of added fluorine in the insulating film 3 of the formed film structure 1 was 0.0344 atm %. The thickness of the insulating film 3 was controlled by the sputtering time determined taking into account the sputter rate.

Next, the vacuum apparatus for carrying out the formation of the insulating film 3 on the carbon material 2 was continuously used to form a Fe₃O₄ film (of 50 nm thickness) on the insulating film 3 in the formed film structure 1 by magnetron sputtering. The formation of the Fe₃O₄ film was carried out using a sintered body of Fe₃O₄ as a target in an argon atmosphere with a pressure of 0.6 Pa under the conditions that the heating temperature was 300° C. and the applied RF power was 100 W. In this manner, a stack of the carbon material 2, the insulating film 3, and the Fe₃O₄ film that were sequentially arranged was obtained (Example 2-1).

A wide-angle X-ray diffraction measurement was performed for the fabricated stack, and the obtained X-ray diffraction profile was evaluated. As a result, a diffraction peak derived from the carbon material 2, a diffraction peak (at a diffraction angle 2θ of)42.9° derived from the (200) plane of the MgO crystal, and a diffraction peak (at a diffraction angle 2θ of)43.1° derived from the (400) plane of the Fe₃O₄ crystal were observed. That is, it was confirmed that a crystal-oriented MgO film and a crystal-oriented Fe₃O₄ film were formed on the carbon material 2. The realization of such a layered structure of a crystal-oriented insulating film and a crystal-oriented magnetic material film, which is suitable for use in an electronic device, is thought to be due to the fact that the insulating film was composed of MgO having added thereto a specific amount of fluorine, and that the degree of lattice mismatch between MgO (having a lattice constant of 0.42 nm) and Fe₃O₄ (having an inverse-spinel structure and a lattice constant of 0.84 nm) is 1% or less.

Next, the Fe₃O₄ film of the fabricated stack was subjected to fine processing by reactive ion etching to form a plurality of strip-shaped Fe₃O₄ films arranged on the insulating film in such a manner that the long sides thereof were parallel to each other. The spin injection properties of the fabricated stack were evaluated using these Fe₃O₄ films as electrodes.

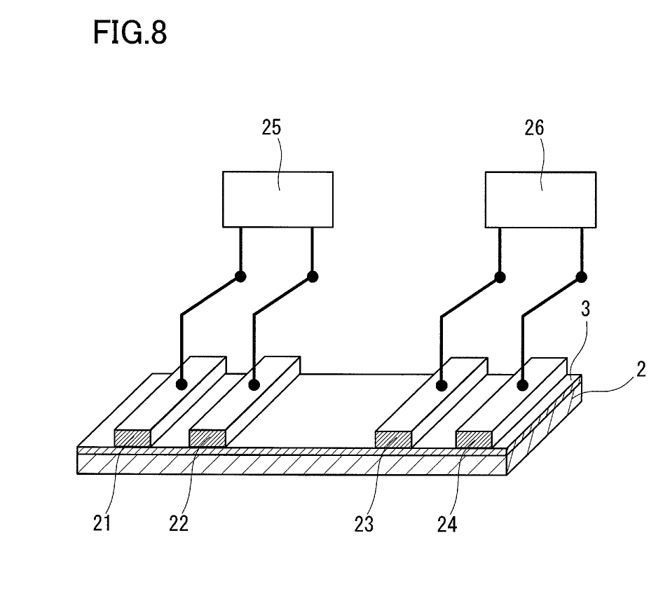

Specifically, the evaluation of the spin injection properties was performed as described below. As shown in FIG. 8, the strip-shaped Fe₃O₄ films formed by fine processing were used as electrodes 21, 22, 23, and 24, and a current source 25 (current source 6221 manufactured by Keithley Instruments) was electrically connected to a pair of the adjacent electrodes 21 and 22. A voltmeter 26 (nanovoltmeter 2182A manufactured by Keithley Instruments) was electrically connected to a pair of the adjacent electrodes 23 and 24 located in the vicinity of the electrodes 21 and 22. Next, a current (of several hundreds of microamperes to several milliamperes) was applied to the electrode 22 from the electrode 21, and the corresponding change in the voltage between the electrode 23 and the electrode 24 was measured to determine whether spins were injected into the carbon material 2 from the Fe₃O₄ films via the insulating film 3. This voltage measurement was substantially identical to the non-local resistance measurement described in Non Patent Literature 1 (Advanced Functional Materials, vol. 19, pp. 3711-3716 (2009)). By sweeping a magnetic field parallel to the plane of the carbon material 2 at the time of measurement of the voltage between the electrodes 23 and 24, spin injection from the Fe₃O₄ films via the insulating film 3 was observed as room-temperature magnetoresistance effect accompanied by hysteresis. That is, it was confirmed that the film structure 1 of Example 1-1 can be used in a spin device in which the insulating film 3 functions as a tunnel insulating film. The Si substrate is omitted from FIG. 8.

Also in the case where a Co₉₀Fe₁₀ alloy film was formed on the insulating film 3 instead of the Fe₃O₄ film, results similar to those in the case where the Fe₃O₄ film was formed were obtained. For the formation of the Co₉₀Fe₁₀ alloy film, the vacuum apparatus for carrying out the formation of the insulating film 3 on the carbon material 2 was continuously used. The formation of the Co₉₀Fe₁₀ alloy film was carried out by magnetron sputtering using a Co₉₀Fe₁₀ alloy as a target in an argon atmosphere with a pressure of 0.8 Pa under the conditions that the heating temperature was 300° C. and the DC voltage applied to the cathode was 400 V. The thickness of the formed Co₉₀Fe₁₀ alloy film was 20 nm. Spin injection from the Co₉₀Fe₁₀ alloy film via the insulating film 3 was observed as room-temperature magnetoresistance effect accompanied by hysteresis.

The present invention may be embodied in other forms without departing from the spirit or essential characteristics thereof. The embodiments disclosed in this specification are to be considered in all respects as illustrative and not limiting. The scope of the present invention is indicated by the appended claims rather than by the foregoing description, and all changes which come within the meaning and range of equivalency of the claims are intended to be embraced therein.

### INDUSTRIAL APPLICABILITY

The film structure of the present invention can be applied, for example, to various electronic devices.

1. A film structure comprising:
a carbon material; and
an insulating film disposed on the carbon material and composed of fluorine-added magnesium oxide, wherein
the amount of added fluorine in the magnesium oxide is 0.0049 atomic percent or more and 0.1508 atomic percent or less.

2. A method for producing a film structure including a carbon material and an insulating film disposed on the carbon material, the method comprising
forming an insulating film composed of fluorine-added magnesium oxide on the carbon material by sputtering using a target containing magnesium oxide and magnesium fluoride, the amount of added fluorine in the insulating film being 0.0049 atomic percent or more and 0.1508 atomic percent or less.

3. The method for producing a film structure according to claim 2, wherein the insulating film is formed on the carbon material by co-sputtering using the target containing magnesium oxide and magnesium fluoride and an additional target composed of magnesium oxide.
